(19) United States
(12) Patent Application Publication
(10) Pub. No.: US 2025/0380427 A1
(43) Pub. Date: Dec. 11, 2025

(54) 3D MEMORY DEVICE USING SELF-SELECTING MEMORY AND OPERATION METHOD OF THE 3D MEMORY DEVICE

(71) Applicant: Samsung Electronics Co., Ltd., Suwon-si (KR)

(72) Inventors: Changseung LEE, Suwon-si (KR); Jooho LEE, Suwon-si (KR); Youngjae KANG, Suwon-si (KR); Sangwook KIM, Suwon-si (KR); Kiyeon YANG, Suwon-si (KR); Minwoo CHOI, Suwon-si (KR)

(73) Assignee: Samsung Electronics Co., Ltd., Suwon-si (KR)

(21) Appl. No.: 18/944,990

(22) Filed: Nov. 12, 2024

(30) Foreign Application Priority Data
Jun. 10, 2024 (KR) 10-2024-0075283

(51) Int. Cl. H10B 63/00; G11C 11/56; G11C 13/00

(52) U.S. Cl. CPC H10B 63/24; G11C 11/56; G11C 13/004; G11C 13/0069; G11C 2213/71; G11C 2213/79

(57) ABSTRACT

Provided are a three-dimensional (3D) memory device using a self-selecting memory and/or an operation method of the 3D memory device. The 3D memory device may include a plurality of memory cells arranged in three dimensions on a substrate. Each of the plurality of memory cells may include a transistor and a self-selecting memory layer connected in series. The transistor may include a channel layer and the channel layer may be parallel to a surface of the substrate. The self-selecting memory layer may include a chalcogenide-based material having Ovonic threshold switching characteristics. The self-selecting memory layer may be configured to have a threshold voltage change according to a polarity and an intensity of an applied voltage.

### CROSS-REFERENCE TO RELATED APPLICATION

This application claims the benefit of Korean Patent Application No. 10-2024-0075283, filed on Jun. 10, 2024, in the Korean Intellectual Property Office, the disclosure of which is incorporated herein in its entirety by reference.

### BACKGROUND

### 1. Field

The disclosure relates to a three-dimensional (3D) memory device using self-selecting memory and/or an operation method of the 3D memory device.

### 2. Description of the Related Art

As miniaturization, multi-function, and/or higher performance of electronic devices may be advantageous, a technology for increasing the degree of integration of higher-capacity semiconductor memory devices may be advantageous. In the case of two-dimensional (2D) semiconductor memory devices, the degree of integration may be determined mainly by the area occupied by each memory cell, and thus, there may be a limit to increasing the degree of integration. Accordingly, three-dimensional (3D) semiconductor memory devices in which memory cells are arranged in three dimensions have been proposed.

### SUMMARY

Provided are a three-dimensional (3D) memory device using a self-selecting memory and/or an operation method of the 3D memory device.

Additional aspects will be set forth in part in the description which follows and, in part, will be apparent from the description, or may be learned by practice of the presented embodiments.

According to an embodiment of the disclosure, a 3D memory device may include a plurality of memory cells arranged in three dimensions on a substrate. Each of the plurality of memory cells may include a transistor and a self-selecting memory layer connected in series. The transistor may include a channel layer and the channel layer may be parallel to a surface of the substrate. The self-selecting memory layer may include a chalcogenide-based material having Ovonic threshold switching characteristics. The self-selecting memory layer may be configured to have a threshold voltage change according to a polarity and an intensity of an applied voltage.

In some embodiments, the transistor may further include a gate electrode on the channel layer and a gate insulating layer between the channel layer and the gate electrode.

In some embodiments, the 3D memory device may further include a plurality of bit lines extending perpendicular to the surface of the substrate. The plurality of memory cells may be arranged along the plurality of bit lines. The plurality of bit lines may be perpendicular to surface of the substrate.

In some embodiments, in each of the plurality of memory cells, the channel layer of the transistor may be connected to a corresponding one of the plurality of bit lines.

In some embodiments, the 3D memory device may further include a plurality of word lines. The plurality of word lines may extend parallel to the surface of the substrate and may intersect the plurality of bit lines.

In some embodiments, in each of the plurality of memory cells, a gate electrode of the transistor may be connected to a corresponding one of the plurality of word lines.

In some embodiments, the 3D memory device may be configured to implement a multi-level memory by changing an intensity of a reset pulse voltage applied to the self-selecting memory layer.

In some embodiments, the self-selecting memory layer may include a chalcogen element and at least one of Ge, As, and Sb. The chalcogen element may include at least one of Se, Te, and S.

In some embodiments, each of the plurality of memory cells may further include a metal layer on one side of the self-selecting memory layer.

In some embodiments, each of the plurality of memory cells may further include an interlayer on both end portions of the self-selecting memory layer.

In some embodiments, the 3D memory device may include a plurality of bit lines on the substrate; and a plurality of select lines on the substrate. The plurality of select lines may be configured to select a selected bit line of the plurality of bit lines.

According to an embodiment of the disclosure, an electronic apparatus may include any one of the 3D memory devices described above.

According to an embodiment of the disclosure, an operation method of a 3D memory device may include selecting a desired memory cell by applying a signal to a selected bit line among a plurality of bit lines and a selected word line among a plurality of word lines. The 3D memory device may include a plurality of memory cells on a substrate at positions where the plurality of bit lines intersect the plurality of word lines. The plurality of bit lines may extend perpendicular to a surface of the substrate. The plurality of word lines may extend parallel to the surface of the substrate and may intersect the plurality of bit lines. Each of the plurality of memory cells may include a transistor and a self-selecting memory layer connected in series. The transistor may include a channel layer parallel to the surface of substrate and a gate electrode on the channel layer. The self-selecting memory layer may include a chalcogenide-based material having Ovonic threshold switching characteristics. The self-selecting memory layer may be configured to have a threshold voltage change according to a polarity and an intensity of an applied voltage.

In some embodiments, the operation method may further include performing a set operation or a reset operation on the desired memory cell by applying a voltage greater than or equal to a threshold voltage of the self-selecting memory layer to the transistor of the desired memory cell through the selected bit line.

In some embodiments, the operation method may further include performing a read operation on the desired memory cell by applying a read voltage to the self-selecting memory layer of the desired memory cell. The read voltage may be less than or equal to a threshold voltage of the self-selecting memory layer.

In some embodiments, the operation method may further include implementing a multi-level memory by changing an intensity of a reset pulse voltage applied to the self-selecting memory layer of the desired memory cell using the selected bit line and the selected word line.

In some embodiments, a polarity of the reset pulse voltage may be different from a polarity of a set pulse voltage.

In some embodiments, the 3D memory device may further include a plurality of select lines on the substrate, and the plurality of select lines may be configured to select the selected bit line among the plurality of bit lines.

In some embodiments, in each of the plurality of memory cells, the channel layer may be connected to a corresponding one of the plurality of bit lines and the gate electrode may be connected to a corresponding one of the plurality of word lines.

In some embodiments, the self-selecting memory layer may include a chalcogen element and at least one of Ge, As, and Sb, the chalcogen element including at least one of Se, Te, and S.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a three-dimensional (3D) memory device according to an embodiment;

FIG. 2 is a cross-sectional view of a memory cell illustrated in FIG. 1;

FIG. 3 is a graph showing an example of voltage-current characteristics of a self-selecting memory layer illustrated in FIG. 2;

FIG. 4A is a graph showing an example of a bias voltage for a set (SET) operation and a read operation applied to the self-selecting memory layer illustrated in FIG. 2;

FIG. 4B is a graph showing an example of a bias voltage for a reset (RESET) operation and a read operation applied to the self-selecting memory layer illustrated in FIG. 2;

FIG. 5 is a graph showing an example of voltage-current characteristics according to a magnitude (intensity) of a write voltage applied to the self-selecting memory layer illustrated in FIG. 2;

FIG. 6 is a schematic view illustrating an example of a circuit diagram of a 3D memory device according to an embodiment;

FIG. 7 is a schematic view illustrating another example of a circuit diagram of a 3D memory device according to an embodiment;

FIGS. 8A and 8B illustrate example structures of a transistor applicable to a memory cell of a 3D memory device according to an embodiment;

FIGS. 9A and 9B illustrate other example structures of a transistor applicable to a memory cell of a 3D memory device according to an embodiment;

FIG. 10 is a conceptual view schematically showing a device architecture applicable to an example electronic apparatus;

FIG. 11 is a block diagram of a memory system according to an embodiment; and

FIG. 12 is a block diagram showing a neuromorphic apparatus according to an embodiment and an external device connected thereto.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”, “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments are described below in detail with reference to the accompanying drawings. Throughout the drawings, like reference numerals denote like elements, and sizes of components in the drawings may be exaggerated for convenience of explanation and clarity. Furthermore, as embodiments described below are examples, other modifications may be produced from the embodiments.

Furthermore, when a constituent element is disposed “above” or “on” to another constituent element, the constituent element may be only directly on the other constituent element or above the other constituent elements in a non-contact manner. As used herein, the singular forms “a,” “an,” and “the” are intended to include the plural forms as well, unless the context clearly indicates otherwise. Furthermore, it will be further understood that the terms “comprises” and/or “comprising” used herein specify the presence of stated features or elements, but do not preclude the presence or addition of one or more other features or elements.

The use of the terms “a,” “an,” “the,” and similar referents in the context of describing the disclosure is to be construed to cover both the singular and the plural. Also, the operations of all methods described herein can be performed in any suitable order unless otherwise indicated herein or otherwise clearly contradicted by context. The disclosure is not limited to the described order of the steps.

Furthermore, terms such as “ . . . portion,” “ . . . unit,” “ . . . module,” and “ . . . block” stated in the disclosure may signify a unit to process at least one function or operation and the unit may be embodied by hardware, software, or a combination of hardware and software.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language (e.g., “such as”) provided herein, is intended merely to better illuminate the disclosure and does not pose a limitation on the scope of the disclosure unless otherwise claimed.

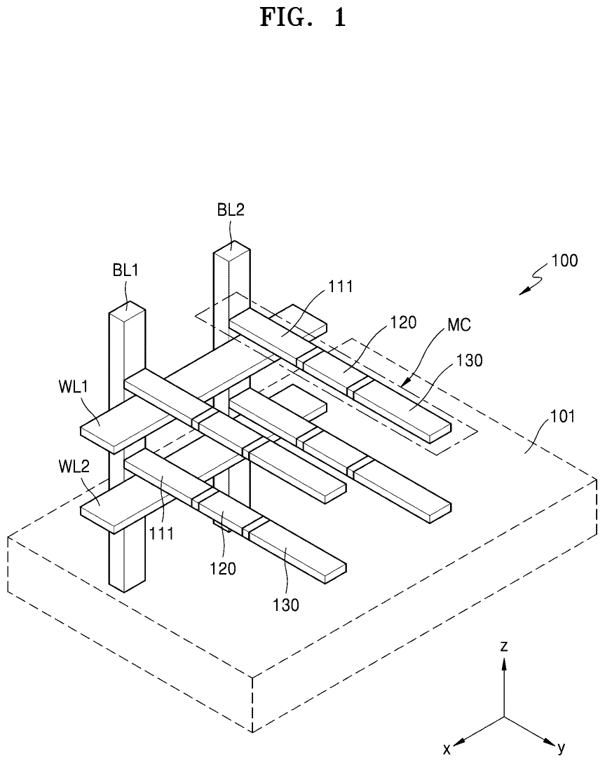

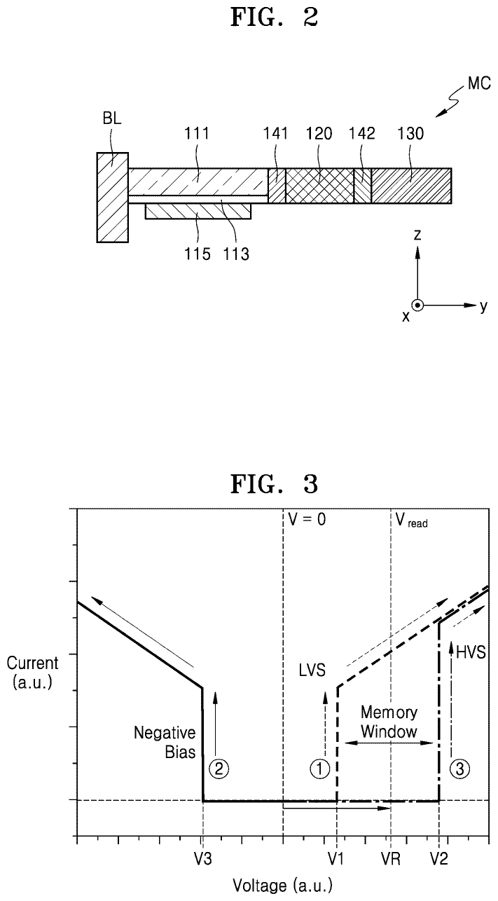

FIG. 1 is a schematic perspective view of a three-dimensional (3D) memory device 100 according to an embodiment. FIG. 2 is a cross-sectional view of a memory cell MC illustrated in FIG. 1.

Referring to FIGS. 1 and 2, the 3D memory device 100 may include a plurality of memory cells MC arranged in three dimensions on a substrate 101. The substrate 101 may include various materials. For example, the substrate 101 may include a single-crystal silicon substrate, a compound semiconductor substrate, or a silicon on insulator (SOI) substrate, but the disclosure is not limited thereto. Furthermore, the substrate 101 may further include, for example, at least one of an impurities region by doping, an electronic device such as a transistor, or a periphery circuit for selecting and controlling memory cells.

A plurality of bit lines BL1 and BL2 may extend on the substrate 101 in a direction (e.g., z-axis direction) that is perpendicular to the substrate 101, and the memory cells MC may be arranged in a direction perpendicular to the substrate 101 along the bit lines BL1 and BL2. Each of the memory cells MC may extend perpendicular to each of the bit lines BL1 and BL2. A plurality of word lines WL1 and WL2 may extend in a direction (e.g., an x-axis direction) parallel to the substrate 101 to intersect the bit lines BL1 and BL2. One end portion of each of the memory cells MC may be electrically connected to a corresponding one of the bit lines BL1 and BL2, and each of the bit lines BL1 and BL2 may function to apply a voltage to each of the memory cells MC.

Each of the memory cells MC may include a transistor connected to a corresponding one of the bit lines BL1 and BL2 and a self-selecting memory layer 120 connected to the transistor. The transistor and the self-selecting memory layer 120 may be connected in series.

The transistor may include a channel layer 111, a gate electrode 115, and a gate insulating layer 113. The channel layer 111 may extend parallel to the substrate 101. The channel layer 111 may extend in a direction parallel to the substrate 101, for example, in a y-axis direction. One end portion of the channel layer 111 may be electrically connected to a corresponding one of the bit lines BL1 and BL2. The other end portion of the channel layer 111 may be electrically connected to the self-selecting memory layer 120.

The channel layer 111 may include a semiconductor material. The channel layer 111 may include, for example, Si, Ge, SiGe, Group III-V semiconductor, or the like. As a detailed example, the channel layer 111 may include poly-Si, but the disclosure is not limited thereto. Furthermore, the channel layer 111 may include, for example, an oxide semiconductor, a nitride semiconductor, an oxynitride semiconductor, a two-dimensional (2D) semiconductor material, quantum dots, or an organic semiconductor. The oxide semiconductor may include, for example, InGaZnO, or the like, the 2D semiconductor material may include, for example, transition metal dichalcogenide (TMD) or graphene. The quantum dots may include colloidal quantum dots (colloidal QD), a nanocrystal structure, or the like. However, this is just an example, and the disclosure is not limited thereto.

The channel layer 111 may further include a dopant. The dopant may include a p-type dopant or an n-type dopant. The p-type dopant may include, for example, a Group III element, such as B, Al, Ga, or In, and the n-type dopant may include, for example, a Group V element, such as P, As, or Sb.

The gate electrode 115 may be provided on one surface of channel layer 111. FIGS. 1 and 2 illustrate an example in which the gate electrode 115 may be provided on a lower surface of the channel layer 111. However, the disclosure is not limited thereto, and the gate electrode 115 may be provided on an upper surface of the channel layer 111. The gate electrode 115 controls the channel layer 111, and the word lines WL1 and WL2 may be electrically connected to the gate electrode 115. The gate electrode 115 may be integrally formed with the word lines WL1 and WL2. A voltage to turn on/off the channel layer 111 may be selectively applied to the gate electrode 115 through the word lines WL1 and WL2.

The gate electrode 115 may include a metal material, a metal nitride, impurity-doped silicon, or a 2D conductive material having excellent conductivity. However, this is just an example, and the gate electrode 115 may include various other materials. The gate insulating layer 113 may be arranged between gate electrode 115 and the channel layer 111. The gate insulating layer 113 may include various types of insulating materials, and for example, silicon oxide, silicon nitride, or silicon oxynitride may be used for the gate insulating layer 113.

The self-selecting memory layer 120 may be connected in series to the transistor including the channel layer 111, the gate electrode 115, and the gate insulating layer 113. One end portion of the channel layer 111 may be electrically connected to a corresponding one of the bit lines BL1 and BL2, and the other end portion of the channel layer 111 may be electrically connected to the self-selecting memory layer 120.

The self-selecting memory layer 120 may have Ovonic threshold switching (OTS) characteristics of having a high resistance state when an input voltage is lower than a threshold voltage and having a low resistance state when the input voltage is higher than the threshold voltage. Furthermore, the self-selecting memory layer 120 may have memory properties in which a threshold voltage is shifted according to the polarity and the intensity of an applied bias voltage. Accordingly, the self-selecting memory layer 120 may have properties to perform both of a memory function and a selector function.

The self-selecting memory layer 120 may include a Chalcogenide-based material. For example, the self-selecting memory layer 120 may include a chalcogen element and at least one of Ge, As, and Sb. The chalcogen element may include at least one of Se, Te, and S. The self-selecting memory layer 120 may further include at least one of In, Al, C, B, Sr, Ga, O, N, Si, Ca, and P. For example, the self-selecting memory layer 120 may include at least one of GeAsSe, GeAsSeIn, GeAsSeSIn, GeAsSeSb, GeAsSeTe, GeAsSeAl, GeAsSeAlIn, GeSbSe, GeAsSeGa, GeSe, GeSeln, GeS, GeSIn, GeCTe, GeCTeN, and GeSbSeN.

FIG. 3 is a graph showing an example of the voltage-current characteristics of the self-selecting memory layer 120 illustrated in FIG. 2.

Referring to FIG. 3, the self-selecting memory layer 120 may have any one state between a first state and a second state. In the first state (low Vth state; LVS), a threshold voltage may be relatively low. In the second state (high Vth state; HVS), the threshold voltage may be relatively high. For example, in the first state, the threshold voltage of the self-selecting memory layer 120 may be a first voltage V1. In the second state, the threshold voltage of the self-selecting memory layer 120 may be a second voltage V2, where the second voltage V2 may be higher than the first voltage V1.

In a case in which the self-selecting memory layer 120 is in the first state, when a voltage lower than the first voltage V1 is applied to the self-selecting memory layer 120, almost no current flows between both ends of the self-selecting memory layer 120, and when a voltage higher than the first voltage V1 is applied to the self-selecting memory layer 120, the self-selecting memory layer 120 may be turned on so that current flows through the self-selecting memory layer 120. Furthermore, in a case in which the self-selecting memory layer 120 is in the second state, when a voltage lower than the second voltage V2 is applied to the self-selecting memory layer 120, almost no current flows between both ends of the self-selecting memory layer 120, and when a voltage higher than the second voltage V2 is applied to the self-selecting memory layer 120, the self-selecting memory layer 120 may be turned on so that current flows through the self-selecting memory layer 120.

Accordingly, a voltage between the first voltage V1 and the second voltage V2 may be selected as a read voltage VR. In a case in which the self-selecting memory layer 120 is in the first state, when the read voltage VR is applied to the self-selecting memory layer 120, current flows through the self-selecting memory layer 120, and in this state, a data value stored in the self-selecting memory layer 120 may be defined as “1.” In a case in which the self-selecting memory layer 120 is in the second state, when the read voltage VR is applied to the self-selecting memory layer 20, almost no current flows through the self-selecting memory layer 120, and in this state, the data value stored in the self-selecting memory layer 120 may be defined as “0.” In other words, when the current flowing in the self-selecting memory layer 120 is measuring while the read voltage VR is applied to the self-selecting memory layer 120, the data value stored in the self-selecting memory layer 120 may be read out.

Meanwhile, in a case in which the self-selecting memory layer 120 is in the first state, when a negative (−) bias voltage is applied to the self-selecting memory layer 120, the threshold voltage of the self-selecting memory layer 120 is increased so that the self-selecting memory layer 120 may be converted into the second state. For example, when a negative third voltage V3 is applied to the self-selecting memory layer 120, the self-selecting memory layer 120 may be converted into the second state. Such an operation may be referred to as a ‘reset (RESET)’ operation. Furthermore, in a case in which the self-selecting memory layer 120 is in the second state, when a positive (+) bias voltage greater than the second voltage V2 is applied to the self-selecting memory layer 120, the threshold voltage of the self-selecting memory layer 120 is decreased so that the self-selecting memory layer 120 may be converted into the first state. Such an operation may be referred to as a ‘set (SET)’ operation. A difference between the second voltage V2 that is a reset (RESET) threshold voltage and the first voltage V1 that is a set (SET) threshold voltage corresponds to a memory window.

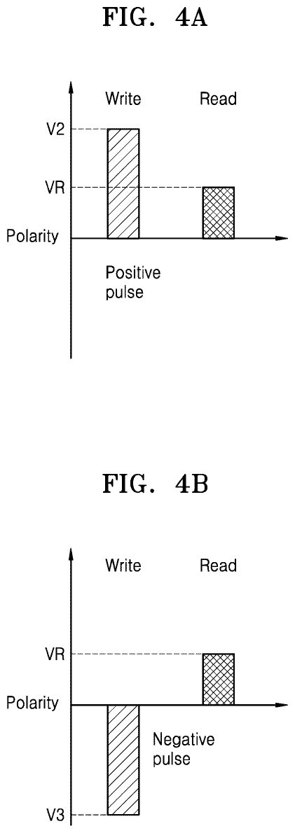

FIG. 4A is a graph showing an example of a bias voltage for a set (SET) operation and a read operation applied to the self-selecting memory layer 120 illustrated in FIG. 2.

Referring to FIG. 4A, in a set (SET) operation, a positive (+) bias voltage greater than or equal to the second voltage V2 may be applied to the self-selecting memory layer 120. Then, the threshold voltage of the self-selecting memory layer 120 may be shifted to the first voltage V1. Thereafter, in a read operation, the positive (+) read voltage VR between the first voltage V1 and the second voltage V2 may be applied to the self-selecting memory layer 120. When the read voltage VR is applied to the self-selecting memory layer 120, the self-selecting memory layer 120 may be turned on.

FIG. 4B is a graph showing an example of a bias voltage for a reset (RESET) operation and a read operation applied to the self-selecting memory layer 120 illustrated in FIG. 2.

Referring to FIG. 4B, in a reset (RESET) operation, a negative (−) bias voltage, that is, the negative third voltage V3 may be applied to the self-selecting memory layer 120. The absolute value of the negative third voltage V3 may be approximately equal to or slightly greater to less than the second voltage V2. Then, the threshold voltage of the self-selecting memory layer 120 may be shifted to the second voltage V2 that is greater than the first voltage V1. Thereafter, in the read operation, the positive (+) read voltage VR between the first voltage V1 and the second voltage V2 may be applied to the self-selecting memory layer 120. When the read voltage VR is applied to the self-selecting memory layer 120, the self-selecting memory layer 120 may not be turned on.

As described above, the self-selecting memory layer 120 may have the Ovonic threshold switching characteristics and simultaneously may have memory properties of changing the threshold voltage. In particular, the threshold voltage of the self-selecting memory layer 120 may be shifted according to the polarity of a bias voltage applied to the self-selecting memory layer 120.

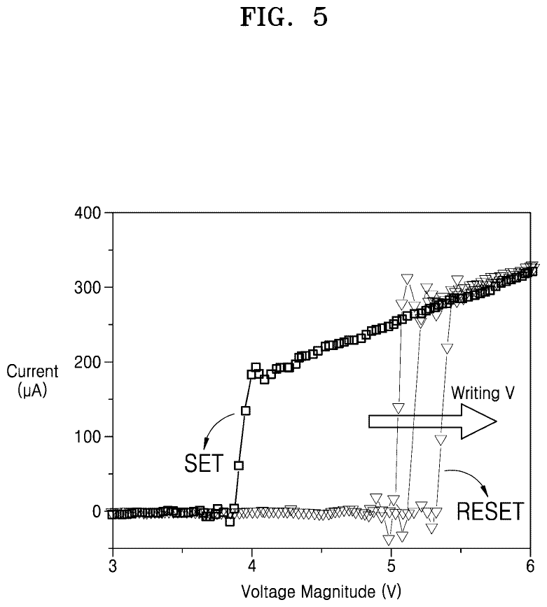

FIG. 5 is a graph showing an example of the voltage-current characteristics according to the magnitude (intensity) of a write voltage applied to the self-selecting memory layer 120 illustrated in FIG. 2.

Referring to FIG. 5, when a write voltage applied to the self-selecting memory layer 120 is, for example, a pulse voltage with a positive (+) polarity, even when the magnitude (intensity) of a voltage increases, the set (SET) threshold voltage does not change. In contrast, when the write voltage applied to the self-selecting memory layer 120 is a pulse voltage, for example, a pulse voltage with a negative (−) polarity, having a different polarity from the set pulse voltage, it may be seen that, as the magnitude (intensity) of a voltage increases, a reset (RESET) threshold voltage increases. Accordingly, by changing the magnitude of a pulse voltage with a negative (−) polarity, the self-selecting memory layer 120 may implement a multi-level memory.

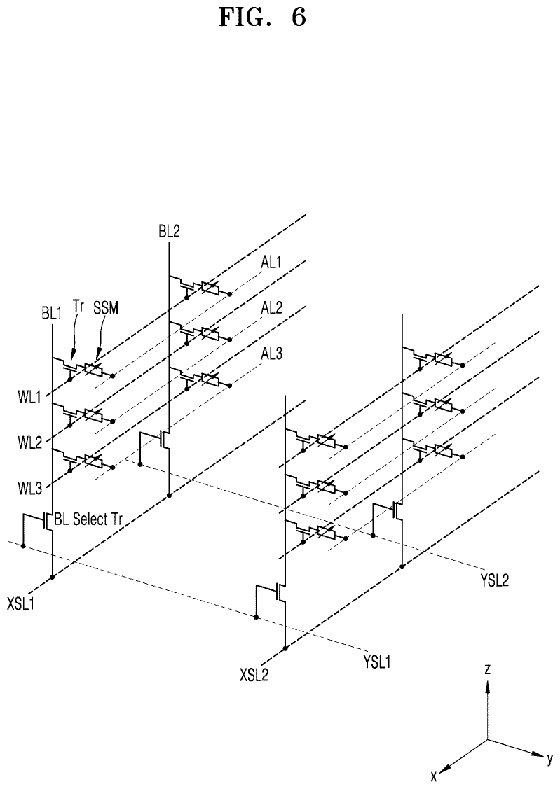

Referring back to FIG. 2, the one end portion of the self-selecting memory layer 120 may be electrically connected to the channel layer 111 of the transistor, and the other end portion of the self-selecting memory layer 120 may be electrically connected to a metal layer 130. The metal layer 130 may be used to apply a voltage to the self-selecting memory layer 120 with the bit lines BL1 and BL2. The metal layer 130 may include, for example, metal, conductive metal nitride, conductive metal oxide, or a combination thereof. However, the disclosure is not limited thereto. The metal layer 130 may be electrically connected to write lines AL1, AL2, and AL3 of FIG. 6 described below.

First and second interlayers 141 and 142 may be further provided in both ends of the self-selecting memory layer 120. The first interlayer 141 may be provided between the channel layer 111 of the transistor and the self-selecting memory layer 120. The second interlayer 142 may be provided between the self-selecting memory layer 120 and the metal layer 130. The first and second interlayers 141 and 142, which function as diffusion barriers, may include, for example, a carbon-based conductive material (e.g., carbon nitride, etc.), but the disclosure is not limited thereto.

FIG. 6 is a schematic view illustrating an example of a circuit diagram of the 3D memory device 100 according to an embodiment illustrated in FIG. 1.

Referring to FIG. 6, the bit lines BL1 and BL2 may be arranged on the substrate 101 of FIG. 1 in the form of a 2D matrix. Each of the bit lines BL1 and BL2 extends in the direction perpendicular to the substrate 101, for example, the z-axis direction. A plurality of memory cells (e.g., the memory cells MC of FIG. 1) may be connected to the bit lines BL1 and BL2. Accordingly, the memory cells MC may be arranged along the bit lines BL1 and BL2 in the direction perpendicular to the substrate 101, for example, the z-axis direction.

As described above, each of the memory cells MC may include a transistor Tr and a self-selecting memory layer SSM connected in series to the transistor Tr. In the circuit diagram illustrated in FIG. 6, “Tr” denotes the transistor illustrated in FIG. 2 which includes the channel layer 111, the gate electrode 115, and the gate insulating layer 113, and “SSM” denotes the self-selecting memory layer 120 illustrated in FIG. 2 which has the characteristics of performing a memory function and a selector function.

The channel layer 111 of the transistor Tr may extend in the direction parallel to the substrate 101, for example, the y-axis direction. One end portion of the channel layer 111 may be electrically connected to a corresponding one of the bit lines BL1 and BL2, and the other end portion of the channel layer 111 may be electrically connected to the self-selecting memory layer SSM. The metal layer 130 of FIG. 2 may be connected to one end portion of the self-selecting memory layer SSM, and the metal layer 130 may be connected to the write lines AL1, AL2, and AL3. The write lines AL1, AL2, and AL3 may extend in the direction parallel to the substrate 101, for example, the x-axis direction.

A plurality of word lines WL1, WL2, and WL3 may intersect the bit lines BL1 and BL2. The word lines WL1, WL2, and WL3 may each extend in the direction parallel to the substrate 101, for example, the x-axis direction. The word lines WL1, WL2, and WL3 may each be connected in common to, for example, the gate electrodes 115 of the transistors Tr arranged in the x-axis direction. A voltage to turn on/off the channel layer 111 may be selectively applied to the gate electrode 115 through the word lines WL1 and WL2. The gate electrode 115 may be integrally formed with the word lines WL1, WL2, and WL3.

The select lines XSL1, XSL2, YSL1, and YSL2 may perform a function to select a desired one of the bit lines BL1 and BL2 may be disposed under the bit lines BL1 and BL2. These select lines XSL1, XSL2, YSL1, and YSL2 may be formed on the upper surface of the substrate 101. The select lines XSL1, XSL2, YSL1, and YSL2 may include the X select lines XSL1 and XSL2. The Y select lines YSL1 and YSL2 which intersect each other. The X select lines XSL1 and XSL2 may each extend in a first direction, for example, the x-axis direction, and the Y select lines YSL1 and YSL2 may each extend in a second direction, for example, the y-axis direction.

A bit line select transistor BL select Tr to select a desired (and/or alternatively predetermined) one of the bit lines BL1 and BL2 may be arranged at each of intersections where the X select lines XSL1 and XSL2 intersect the Y select lines YSL1 and YSL2. The X select lines XSL1 and XSL2 and the bit lines BL1 and BL2 may be respectively connected to a source and a drain of the bit line select transistor BL select Tr, and each of the Y select lines YSL1 and YSL2 may be connected to a gate of the bit line select transistor BL select Tr.

In the circuit diagram of the 3D memory device 100 illustrated in FIG. 6, desired one of the bit lines BL1 and BL2 may be selected by applying a signal to each of a desired (and/or alternatively predetermined) one of the X select lines XSL1 and XSL2 and a desired (and/or alternatively predetermined) one of the Y select lines YSL1 and YSL2 to drive a desired (and/or alternatively predetermined) bit line select transistor BL select Tr. The memory cell MC for a write or read operation may be selected by applying a voltage to a desired (and/or alternatively predetermined) one of the word lines WL1, WL2, and WL3 intersecting the selected one of the bit lines BL1 and BL2. In order for the channel layer 111 of the selected memory cell MC to be in a channel on-state, a certain voltage may be applied to the gate electrode 115 through one of the word lines WL1, WL2, and WL3.

When a write operation is performed on the selected memory cell MC, a set operation or reset operation may be performed on the selected memory cell MC by applying a voltage greater than or equal to the threshold voltage of the self-selecting memory layer SSM to the transistor Tr through one of the bit lines BL1 and BL2. As described above, when the voltage applied to the self-selecting memory layer SSM is a pulse voltage having a different polarity from that of a set pulse voltage, for example, a pulse voltage with a negative (−) polarity, as the magnitude (intensity) of a voltage increases, a reset (RESET) threshold voltage may increase. Accordingly, by changing the magnitude of a pulse voltage with a negative (−) polarity applied to the self-selecting memory layer SSM, the self-selecting memory layer SSM may implement a multi-level memory.

When a read operation is performed on the selected memory cell MC, a read operation may be performed on the selected memory cell MC by applying a voltage less than or equal to the threshold voltage of the self-selecting memory layer SSM to the transistor TR through one of the bit lines BL1 and BL2. As a voltage less than or equal to the threshold voltage of the self-selecting memory layer SSM may be used as the read voltage, a non-destructive read operation may be performed.

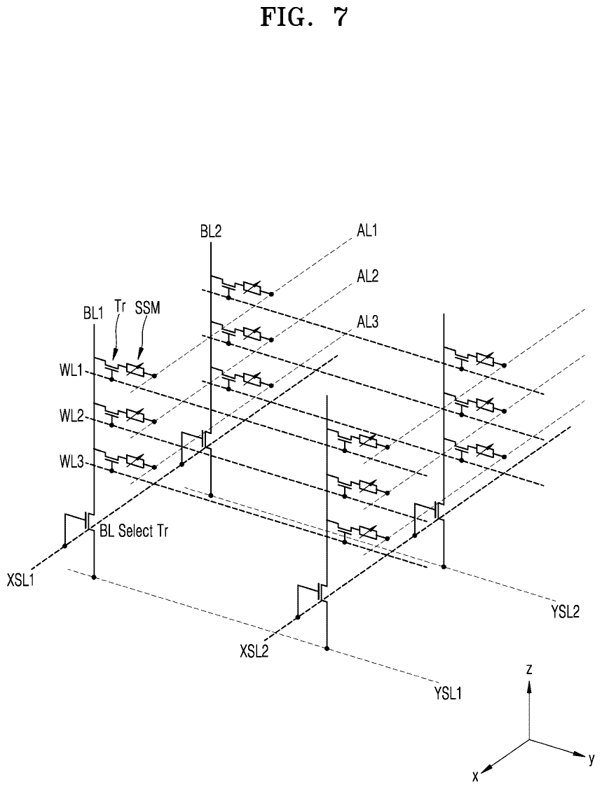

FIG. 7 is a schematic view illustrating another example of a circuit diagram of the 3D memory device 100 according to an embodiment illustrated in FIG. 1. In the following description, differences from the circuit diagram illustrated in FIG. 6 are mainly described.

Referring to FIG. 7, the bit lines BL1 and BL2 each may extend in the direction perpendicular to the substrate 101 on the substrate 101, and the memory cells MC may be arranged along each of the bit lines BL1 and BL2 in the direction perpendicular to the substrate 101.

Each of the memory cells MC may include the transistor Tr and the self-selecting memory layer SSM connected in series to the transistor Tr. The channel layer 111 of the transistor Tr may extend in the direction parallel to the substrate 101. One end portion of the channel layer 111 may be electrically connected to a corresponding one of the bit lines BL1 and BL2, and the other end portion of the channel layer 111 may be electrically connected to the self-selecting memory layer SSM. The metal layer 130 of FIG. 2 may be connected to one end portion of the self-selecting memory layer SSM, and the metal layer 130 may be connected to the write lines AL1, AL2, and AL3.

The word lines WL1, WL2, and WL3 may intersect the bit lines BL1 and BL2. The word lines WL1, WL2, and WL3 may be respectively connected in common to, for example, the gate electrodes 115 of the transistors Tr arranged in the x-axis direction. The select lines XSL1, XSL2, YSL1, and YSL2 may perform a function to select a desired one of the bit lines BL1 and BL2 may be disposed under the bit lines BL1 and BL2.

The select lines XSL1, XSL2, YSL1, and YSL2 may include the X select lines XSL1 and XSL2 and the Y select lines YSL1 and YSL2 intersecting each other. The X select lines XSL1 and XSL2 may each extend in the first direction, for example, the x-axis direction. The Y select lines YSL1 and YSL2 may each extend in the second direction, for example, the y-axis direction.

The bit line select transistor BL select Tr may be used to select a desired (and/or alternatively predetermined) one of the bit lines BL1 and BL2 and may be arranged at each of intersections where the X select lines XSL1 and XSL2 intersect the Y select lines YSL1 and YSL2. The Y select lines YSL1 and YSL2 and the bit lines BL1 and BL2 may be respectively connected to a source and a drain of the bit line select transistor BL select Tr. The X select lines XSL1 and XSL2 may be connected to a gate of the bit line select transistor BL select Tr.

In the circuit diagram of the 3D memory device 100 illustrated in FIG. 7, desired one of the bit lines BL1 and BL2 may be selected by applying a signal to each of a desired (and/or alternatively predetermined) one of the X select lines XSL1 and XSL2 and a desired (and/or alternatively predetermined) one of the Y select lines YSL1 and YSL2 to drive a desired (and/or alternatively predetermined) bit line select transistor BL select Tr. The memory cell MC for a write or read operation may be selected by applying a voltage to a desired (and/or alternatively predetermined) one of the word lines WL1, WL2, and WL3 intersecting the selected one of the bit lines BL1 and BL2.

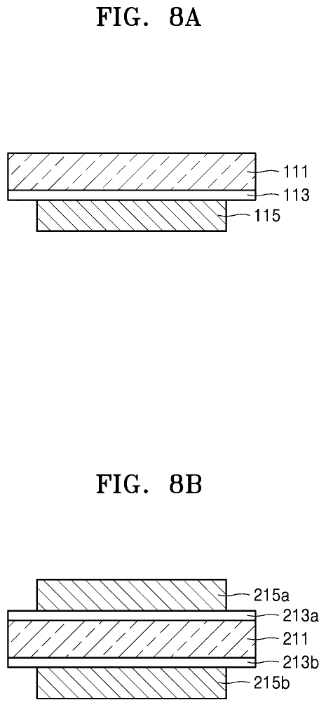

FIGS. 8A and 8B illustrate example structures of a transistor applicable to the memory cell MC of the 3D memory device 100 according to an embodiment.

FIG. 8A illustrates a case in which, as illustrated in FIG. 2, a transistor may include one channel layer 111 and one gate electrode 115. Referring to FIG. 8A, the transistor may include the channel layer 111 and the gate electrode 115 provided under the channel layer 111. The gate insulating layer 113 may be provided between the channel layer 111 and the gate electrode 115. Although FIG. 8A illustrates an example in which the gate electrode 115 is provided under the channel layer 111, the gate electrode 115 may be provided above the channel layer 111.

FIG. 8B illustrates a case in which a transistor may include one channel layer 211 and two gate electrodes 215a and 215b. Referring to FIG. 8B, the transistor may include the channel layer 211, the first gate electrode 215a provided above the channel layer 211, and the second gate electrode 215b provided under the channel layer 211. A first gate insulating layer 213a may be provided between the channel layer 211 and the first gate electrode 215a, and a second gate insulating layer 213b may be provided between the channel layer 211 and the second gate electrode 215b.

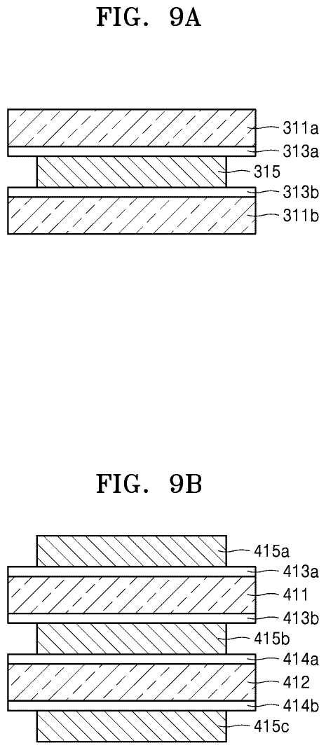

FIGS. 9A and 9B illustrate other example structures of a transistor applicable to the memory cell MC of the 3D memory device 100 according to an embodiment.

FIG. 9A illustrates a case in which a transistor may include one gate electrode 315 and two channel layers 311a and 311b. Referring to FIG. 9A, the transistor may include the gate electrode 315, the first channel layer 311a provided above the gate electrode 315, and the second channel layer 311b provided under the gate electrode 315. A first gate insulating layer 313a may be provided between the gate electrode 315 and the first channel layer 311a, and a second gate insulating layer 313b may be provided between the gate electrode 315 and the second channel layer 311b.

FIG. 9B illustrates a case in which a transistor may include two channel layers 411 and 412 and three gate electrodes 415a, 415b, and 415c. Referring to FIG. 9B, the transistor may include the first and second channel layers 411 and 412 arranged apart from each other, the first gate electrode 415a provided above the first channel layer 411, the second gate electrode 415b provided between the first and second channel layers 411 and 412, and the third gate electrode 415c provided under the second channel layer 412. First and second gate insulating layers 413a and 413b may be provided on the upper surface and the lower surface of the first channel layer 411, respectively, and third and fourth gate insulating layers 414a and 414b may be provided on the upper surface and the lower surface of the second channel layer 412, respectively. The structures of the transistors illustrated in FIGS. 8A and 8B, and FIGS. 9A and 9B described above are just examples, and the transistor may have various other structures.

As described above, in the 3D memory device 100 according to an embodiment, each of the memory cells MC may have a structure in which the transistor Tr and the self-selecting memory layer SSM capable of performing both of a memory function and a selector function are connected in series. In other words, as each of the memory cells MC may have a structure in which two switching elements are connected in series, a leakage current may be controlled in two ways. For example, even when the transistor is in an on-state, the memory cell MC may maintain an off-state at a voltage that is less than or equal to a certain voltage (e.g., about 1 V). Accordingly, the 3D memory device 100 with reduced leakage current and/or standby power may be implemented.

The 3D memory device 100 according to an embodiment having the self-selecting memory layer SSM having trap-based memory properties and may be capable of sub-nanosecond switching, and thus, faster high-speed memory properties may be implemented.

In the 3D memory device 100 according to an embodiment, in order to perform a read operation on the memory cells MC, a voltage less than or equal to the threshold voltage of the self-selecting memory layer SSM may be used as a read voltage, and thus, a non-destructive read operation is possible. Furthermore, as memory refresh that is essentially required in DRAM is not necessary in the 3D memory device 100 according to an embodiment, operation may be simplified and consumption power may be improved.

In the 3D memory device 100 according to an embodiment, by changing the magnitude of a reset pulse voltage applied to the self-selecting memory layer SSM, multi-level memory properties may be implemented, and the memory window may be easily adjusted.

In a 3D memory device having a cross point array structure, which does not use a transistor, an IR drop problem may occur due to long lengths of bit lines and word lines. In the 3D memory device 100 according to an embodiment, each of the memory cells MC may include the transistor Tr connected in series to the self-selecting memory layer SSM so that the IR drop problem may be reduced. Furthermore, in the 3D memory device 100 according to an embodiment, as an operation current of the self-selecting memory layer SSM can be controlled by adjusting a gate voltage applied to the transistor Tr, a write power may be reduced.

The 3D memory device 100 according to an embodiment described above may be used for storing data in various electronic apparatuses. For example, the 3D memory device 100 likely may be used in the fields of neuromorphic computing, in-memory computing, AI training & inference which may require large capacity, and may be applied in various other fields.

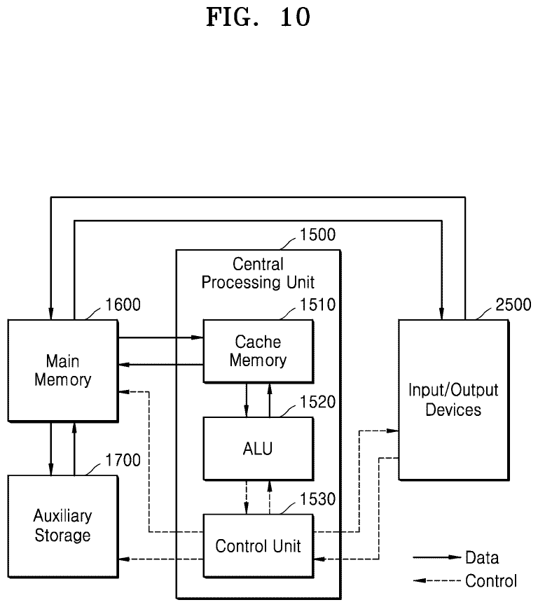

FIG. 10 is a conceptual view schematically showing a device architecture applicable to an example electronic apparatus.

Referring to FIG. 10, a cache memory 1510, an ALU 1520, and a control unit 1530 may be in a central processing unit (CPU) 1500, and the cache memory 1510 may include a static random access memory (SRAM). Separately from the CPU 1500, a main memory 1600 and an auxiliary storage 1700 may be provided. The main memory 1600 may include a DRAM device, and the auxiliary storage 1700 may include the 3D memory device 100 described above. In some cases, a device architecture may be implemented in the form of one chip in which computing unit elements and memory unit elements are adjacent to each other, without distinction of sub-units. In some cases, the device architecture may include input/output devices 2500 (e.g., keyboard, mouse, display).

The 3D memory device 100 according to an embodiment described above, which is implemented as a chip type memory block, may be used as a neuromorphic computing platform or used in a neural network.

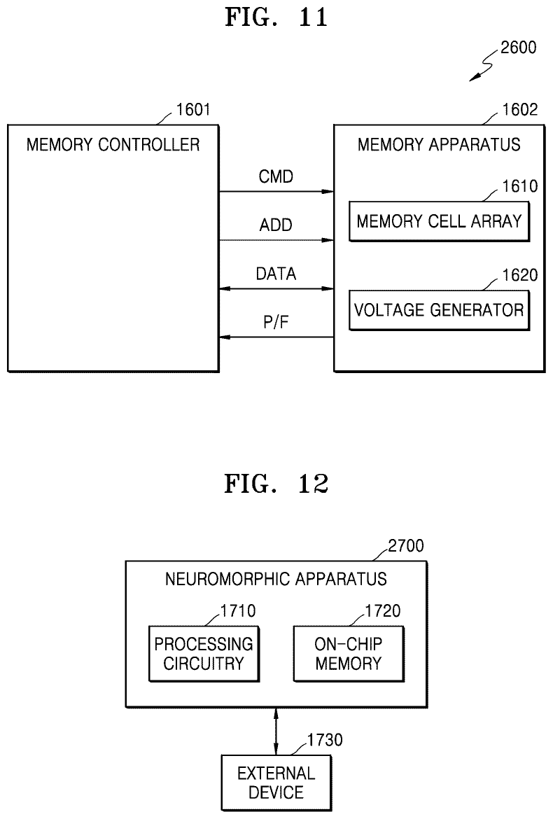

FIG. 11 is a block diagram of a memory system 2600 according to an embodiment.

Referring to FIG. 11, the memory system 2600 may include a memory controller 1601 and a memory apparatus 1602. The memory controller 1601 may perform a control operation on the memory apparatus 1602. For example, the memory controller 1601 may provide the address ADD to the memory apparatus 1602 and a command CMD to perform programming (or writing), read, and/or erase operations on the memory apparatus 1602 to the memory apparatus 1602. Furthermore, data for a programming operation and a read operation may be transmitted between the memory controller 1601 and the memory apparatus 1602.

The memory apparatus 1602 may include a memory cell array 1610 and a voltage generator 1620. The memory cell array 1610 may include a plurality of memory cells and include the 3D memory device 100 according to an embodiment described above.

The memory controller 1601 may include a processing circuitry such as hardware including a logic circuit, a hardware/software combination such as a processor that executes software, or a combination thereof. For example, the processing circuitry may include, in detail, a central processing device (CPU), an arithmetic logic unit (ALU), a digital signal processor, a microcomputer, a field programmable gate array (FPGA), a system-on-chip (SoC), a programmable logic unit, a microprocessor, or an application-specific integrated circuit (ASIC), but the disclosure is not limited thereto. The memory controller 1601 may be configured to operate in response to a request from a host (not shown), access the memory apparatus 1602, and control the control operations (e.g., a write/read operation) discussed above, thereby converting the memory controller 1601 into a special purpose controller. The memory controller 1601 may generate an address ADD and the command CMD to perform programming/read/erase operations on the memory cell array 1610. Furthermore, in response to the command CMD from the memory controller 1601, the voltage generator 1620 (e.g., a power circuit) may generate a voltage control signal to control a voltage level of a word line for data programming or data reading with respect to the memory cell array 1610.

Furthermore, the memory controller 1601 may perform a determination operation on the data read from the memory apparatus 1602. For example, the number of on-cells and/or the number of off-cells may be determined from the data read from the memory cells. The memory apparatus 1602 may provide a pass/fail signal P/F to the memory controller 1601 according to a read result of the read data. The memory controller 1601 may control write and read operations on the memory cell array 1610 by referring to the pass/fail signal P/F.

FIG. 12 is a block diagram showing a neuromorphic apparatus 2700 according to an embodiment and an external device connected thereto.

Referring to FIG. 12, the neuromorphic apparatus 2700 may include processing circuitry 1710 and/or an on-chip memory 1720. The neuromorphic apparatus 2700 may include the 3D memory device 100 according to an embodiment described above.

In some embodiments, the processing circuitry 1710 may be configured to control a function to drive the neuromorphic apparatus 2700. For example, the processing circuitry 1710 may be configured to control the neuromorphic apparatus 2700 by executing a program stored in the on-chip memory 1720. In some embodiments, the processing circuitry 1710 may include a processing circuitry such as hardware including a logic circuit, a hardware/software combination such as a processor that executes software, or a combination thereof. For example, the processor may include a CPU, a graphics processing device (GPU), an application processor (AP) included in the neuromorphic apparatus 2700, an ALU, a digital signal processor, a microcomputer, an FPGA, an SoC, a programmable logic unit, a microprocessor, or an ASIC, but the disclosure is not limited thereto. In some embodiments, the processing circuitry 1710 may be configured to read/write various pieces of data with respect to an external device 1730 and/or execute the neuromorphic apparatus 2700 using the read/written data. In some embodiments, the external device 1730 may include an external memory having an image sensor (e.g., a CMOS image sensor circuit) and/or a sensor array.

In some embodiments, the neuromorphic apparatus 2700 of FIG. 12 may be applied to a machine learning system. Such machine learning systems may utilize various artificial neural network organizational and processing models, such as convolutional neural networks (CNN), de-convolutional neural networks, recurrent neural networks (RNN) optionally including long short-term memory (LSTM) units and/or gated recurrent units (GRU), stacked neural networks (SNN), state-space dynamic neural networks (SSDNN), deep belief networks (DBN), generative adversarial networks (GANs), and/or restricted Boltzmann machines (RBM).

Alternatively or additionally, such machine learning systems may include other forms of machine learning models, such As, for example, linear and/or logistic regression, statistical clustering, Bayesian classification, decision trees, dimensionality reduction such as principal component analysis, and expert systems; and/or combinations thereof, including ensembles such as random forests. Such machine learning models may be used to provide various services and/or applications, for example, an image classify service, a user authentication service based on bio-information or biometric data, an advanced driver assistance system (ADAS) service, a voice assistant service, an automatic speech recognition (ASR) service, or the like, and may be executed by other electronic devices.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the 3D memory device 100 according to an embodiment described above have been described with reference to the figures, it will be understood by those of ordinary skill in the art that various changes in form and details may be made therein without departing from the spirit and scope as defined by the following claims.

What is claimed is:

1. A three-dimensional (3D) memory device comprising:
a plurality of memory cells arranged in three dimensions on a substrate, wherein
each of the plurality of memory cells includes a transistor and a self-selecting memory layer connected in series,
the transistor includes a channel layer and the channel layer is parallel to a surface of the substrate,
the self-selecting memory layer includes a chalcogenide-based material having Ovonic threshold switching characteristics, and
the self-selecting memory layer is configured to have a threshold voltage change according to a polarity and an intensity of an applied voltage.

2. The 3D memory device of claim 1, wherein the transistor further comprises:
a gate electrode on the channel layer; and
a gate insulating layer between the channel layer and the gate electrode.

3. The 3D memory device of claim 2, further comprising:
a plurality of bit lines extending perpendicular to the surface of the substrate, wherein
the plurality of memory cells are arranged along the plurality of bit lines.

4. The 3D memory device of claim 3, wherein
in each of the plurality of memory cells, the channel layer of the transistor is connected to a corresponding one of the plurality of bit lines.

5. The 3D memory device of claim 4, further comprising:
a plurality of word lines, wherein
the plurality of word lines extend parallel to the surface of the substrate and intersect the plurality of bit lines.

6. The 3D memory device of claim 5, wherein
in each of the plurality of memory cells, a gate electrode of the transistor is connected to a corresponding one of the plurality of word lines.

7. The 3D memory device of claim 1, wherein
the 3D memory device is configured to implement a multi-level memory based on changing an intensity of a reset pulse voltage applied to the self-selecting memory layer.

8. The 3D memory device of claim 1, wherein
the self-selecting memory layer comprises a chalcogen element and at least one of Ge, As, and Sb, and
the chalcogen element includes at least one of Se, Te, and S.

9. The 3D memory device of claim 1, wherein each of the plurality of memory cells further comprises a metal layer on one side of the self-selecting memory layer.

10. The 3D memory device of claim 9, wherein each of the plurality of memory cells further comprises an interlayer on both end portions of the self-selecting memory layer.

11. The 3D memory device of claim 1, further comprising:
a plurality of bit lines on the substrate; and
a plurality of select lines on the substrate, wherein
the plurality of select lines are configured to select a selected bit line of the plurality of bit lines.

12. An electronic apparatus comprising:
the 3D memory device of claim 1.

13. An operation method of a three-dimensional (3D) memory device, the operation method comprising:
selecting a desired memory cell by applying a signal to a selected bit line among a plurality of bit lines and a selected word line among a plurality of word lines, wherein
the 3D memory device includes a plurality of memory cells on a substrate at positions where the plurality of bit lines intersect the plurality of word lines,
the plurality of bit lines extend perpendicular to a surface of the substrate,
the plurality of word lines extend parallel to the surface of the substrate and intersect the plurality of bit lines,
each of the plurality of memory cells includes
a transistor and a self-selecting memory layer connected in series,
the transistor includes a channel layer parallel to the surface of substrate and a gate electrode on the channel layer,
the self-selecting memory layer includes a chalcogenide-based material having Ovonic threshold switching characteristics, and
the self-selecting memory layer is configured to have a threshold voltage change according to a polarity and an intensity of an applied voltage.

14. The operation method of claim 13, further comprising:
performing a set operation or a reset operation on the desired memory cell by applying a voltage greater than or equal to a threshold voltage of the self-selecting memory layer to the transistor of the desired memory cell through the selected bit line.

15. The operation method of claim 13, further comprising:
performing a read operation on the desired memory cell by applying a read voltage to the self-selecting memory layer of the desired memory cell, and
the read voltage is less than or equal to a threshold voltage of the self-selecting memory layer.

16. The operation method of claim 13, further comprising:
implementing a multi-level memory by changing an intensity of a reset pulse voltage applied to the self-selecting memory layer of the desired memory cell using the selected bit line and the selected word line.

17. The operation method of claim 16, wherein a polarity of the reset pulse voltage is different from a polarity of a set pulse voltage.

18. The operation method of claim 13, wherein
the 3D memory device further includes a plurality of select lines on the substrate, and
the plurality of select lines are configured to select the selected bit line among the plurality of bit lines.

19. The operation method of claim 13, wherein
in each of the plurality of memory cells, the channel layer is connected to a corresponding one of the plurality of bit lines and the gate electrode is connected to a corresponding one of the plurality of word lines.

20. The operation method of claim 13, wherein
the self-selecting memory layer comprises a chalcogen element and at least one of Ge, As, and Sb, and
the chalcogen element comprises at least one of Se, Te, and S.
